(19) United States
(12) Patent Application Publication
(10) Pub. No.: US 2004/0150472 A1
(43) Pub. Date: Aug. 5, 2004

(54) Fault tolerant micro-electro mechanical actuators

(76) Inventor: Thomas F. Rust, Oakland, CA (US)

Correspondence Address: FLIESLER MEYER, LLP, FOUR EMBARCADERO CENTER, SUITE 400, SAN FRANCISCO, CA, 94111, US

(21) Appl. No.: 10/684,760

(22) Filed: Oct. 14, 2003

Related U.S. Application Data
(60) Provisional application No. 60/418,612, filed on Oct. 15, 2002.

(51) Int. Cl. H03F 1/00

(52) U.S. Cl. 330/66

(57) ABSTRACT

A molecular memory integrated circuit in accordance with one embodiment of the present invention can include a set of actuators capable of moving a platform. The platform can contain one of a memory device and a Molecular Array Read/Write Engine (MARE) having a cantilever system including at least one cantilever tip. When the memory device platform is brought within close proximity of the MARE platform, the set of actuators can position the at least one cantilever tip to a specific location on the memory device. The at least one cantilever tip can perform a number of functions to the memory device, including reading the state of the memory device or changing the state of the memory device. In other embodiments, a plurality of actuators is capable of moving a plurality of platforms.

### PRIORITY CLAIM

This application claims priority to the following U.S. Provisional Patent Application:

U.S. Provisional Patent Application No. 60/418,612 entitled “Tault Tolerant Micro-Electro Mechanical Actuators,” Attorney Docket No. LAZE-01015US0, filed Oct. 15, 2002.

### CROSS-REFERENCE TO RELATED PATENT APPLICATIONS

U.S. patent application Ser. No. ______, entitled “Molecular Memory Integrated Circuit Utilizing Non-Vibrating Cantilevers,” Attorney Docket No. LAZE-01011US1, filed herewith;

U.S. patent application Ser. No. ______, entitled “Atomic Probes and Media for high Density Data Storage,” Attorney Docket No. LAZE-01014US1, filed herewith;.

U.S. patent application Ser. No. ______, entitled “Phase Change Media for High Density Data Storage,” Attorney Docket No. LAZE-01019US1, filed herewith;

U.S. Provisional Patent Application No. 60/418,616 entitled “Molecular Memory Integrated Circuit Utilizing Non-Vibrating Cantilevers,” Attorney Docket No. LAZE-01011US0, filed Oct. 15, 2002;

U.S. Provisional Patent Application No. 60/418,923 entitled “Atomic Probes and Media for High Density Data Storage,” Attorney Docket No. LAZE-01014US0, filed Oct. 15, 2002;

U.S. Provisional Patent Application No. 60/418,618 entitled “Molecular Memory Integrated Circuit,” Attorney Docket No. LAZE-01016US0, filed Oct. 15, 2002;

U.S. Provisional Patent Application No. 60/418,619 entitled “Phase Change Media for High Density Data Storage,” Attorney Docket No. LAZE-01019US0, filed Oct. 15, 2002.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### BACKGROUND OF THE INVENTION

1. Field of the Invention

This invention relates to memory on data storage devices and in particular in molecular memory integrated circuits. More particularly, the invention relates to molecular memory integrated circuits for use in micro-electro mechanical systems (MEMS).

2. Description of the Related Art

Current generation computer systems use separately manufactured integrated circuits and components assembled on or connected with system boards. Non-volatile data storage is one of the most performance critical components in a computer system. Current systems suffer from data storage technology incapable of matching the performance of other system components, such as volatile memory and microprocessors. Next generation systems will require improved performance from data storage devices.

Nearly every personal computer and server in use today contains one or more hard disk drives for permanently storing frequently accessed data. Every mainframe and supercomputer is connected to hundreds of hard disk drives. Consumer electronic goods ranging from camcorders to TiVo® use hard disk drives. While hard disk drives store large amounts of data, they consume a great deal of power, require long access times, and require “spin-up” time on power-up.

FLASH memory is a more readily accessible form of data storage and a solid-state solution to the lag time and high power consumption problems inherent in hard disk drives. Like hard disk drives, FLASH memory can store data non-volatilely, but the cost per megabyte is dramatically higher than the cost per megabyte of an equivalent amount of space on a hard disk drive, and is therefore sparingly used.

Current solutions for data storage cannot meet the demands of current technology, and are inadequate and impractical for use in next generation systems, such as MEMS. Consequently, it would be desirable to have an integrated circuit that stores data non-volatilely, that can be accessed instantaneously on power-up, that has relatively short access times for retrieving data, that consumes a fraction of the power consumed by a hard disk drive, and that can be manufactured relatively cheaply. Such an integrated circuit would increase performance and eliminate wait time for power-up in current computer systems, increase the memory capacity of portable electronics without a proportional increase in cost and battery requirements, and enable memory storage for next generation systems such as MEMS.

### SUMMARY OF THE INVENTION

A molecular memory integrated circuit includes a set of actuators capable of moving a platform. One embodiment includes a plurality of actuators and platforms. The platform may contain either a memory device or a Molecular Array Read/Write Engine (MARE) with a cantilever system, which includes a cantilever tip. When a first platform with a memory device is brought within close proximity of a second platform with a MARE, the actuators can position the cantilever tip to a specific location on the memory device. The tip of the cantilever can perform a number of functions to the memory device, including reading the state of the memory device or changing the state of the memory device.

### BRIEF DESCRIPTION OF THE DRAWINGS

Further details of the present invention are explained with the help of the attached drawings in which:

FIG. 1 is a die of an embodiment of the invention that includes a number of cells where each cell further includes an interconnect, an actuator, a pull-rod, and a platform

FIG. 2 is a cell of the embodiment of the invention of FIG. 1 that includes a MARE.

FIG. 3 is a scanning electron microscope picture of a cell of the embodiment of the invention of FIG. 1 including a MARE.

FIG. 4 is a cell of the embodiment of the invention that includes a memory devices.

FIG. 5a is a schematical representation of an embodiment of the invention with two platforms, one above the other, where the top platform holds a MARE with a cantilever system and the bottom platform holds a memory device.

FIG. 5b is the schematical representation of FIG. 5a with a tip of a cantilever on a platform holding a MARE making contact with a memory device that is held by a second platform.

FIG. 6 is a gross positioning grid of an embodiment of the invention.

FIG. 7 is an embodiment of an actuator of the invention.

FIG. 8 is a two-dimensional cross-section view of an actuator arm as depicted in FIG. 7 at line 8-8.

FIG. 9 is a three-dimensional cross-section view of an actuator arm as defeated in FIG. 7 at line 9-9.

FIG. 10 is a simple resistor model for an actuator.

### DETAILED DESCRIPTION OF THE DRAWINGS

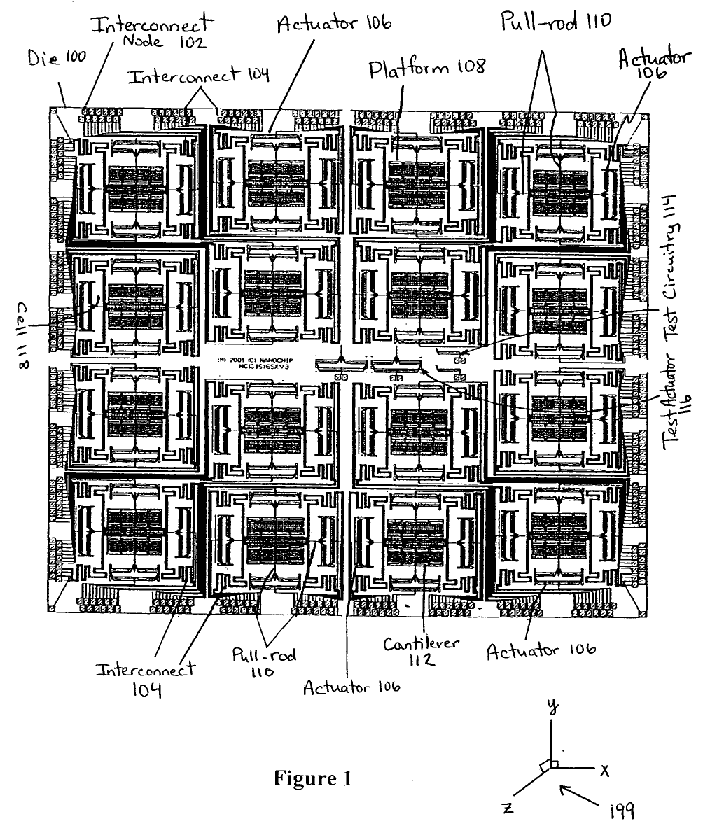

Referring to FIG. 1, die 100 is a device that includes sixteen cells 118 as well as many interconnect nodes 102 and many interconnects 104. Each cell 118 includes four actuators 106, four pull-rods 110, a platform 108, and sixteen cantilevers 112. The interconnect node 102 maybe coupled with interconnect 104, which in turn is coupled with at least one of the cells 118. Interconnect 104 is also connected with various structures on the individual cells 118. For instance, an interconnect 104 is connected with the platform 108. Another interconnect 104 is connected with cantilever 112. Yet another interconnect is connected with actuator 106. Actuator 106, however, is also connected with pull-rod 110. Pull-rod 110 is also connected with platform 108.

Interconnect 104 maybe made from any number of conductive materials. For instance, interconnect 104 could be made from aluminum or copper. Yet, as discussed below, the material chosen for interconnect 104 should have a higher coefficient of expansion than the material chosen for the arms of actuator 106.

Interconnect nodes 102 provide access to the die 100 from sources outside of the die 100, and interconnects 104 provide the pathway for outside sources to communicate with individual cells 118 and the components contained on such cells 118. For instance, sense and control signals maybe passed to and read from actuator 106 to determine its relative position from a neutral state. Different signals may be sent to a cantilever 112 to determine the position of cantilever 112 and/or direct the cantilever 112 to read and/or write data to a memory device. Also, the position of platform 108 may also be detected by devices not included on die 100 through signals passed through interconnect node 102 and interconnect 104. Many other signals and readings maybe made through interconnect node 102 and interconnect 104 as desired by the design of the die 100, the design of the system incorporating die 100, and other design goals.

In addition to sensing the location of platform 108 and actuators 106 through interconnect node 102 and interconnect 104 on die 100, control signals maybe passed through interconnect node 102 and interconnect 104 to direct the actuators 106 to perform some action. For instance, a stimulus maybe sent by an outside device directing a particular actuator 106 to actuate, moving only one platform 108 along either the X-axis or Y-axis as defined by reference 119. A control signal could also be directed to one or more actuators 106 at the same time directing multiple platforms 108 to move in different directions along the X-axis, different directions along the Y-axis, in different directions in both the X-axis and Y-axis, or in the same direction as defined by reference 199. The sixteen cells 118 on die 100 may all be controlled simultaneously, individually, or they may be multiplexed. If cells 118 are multiplexed, then additional multiplexing circuitry is required, but as shown in FIG. 1, cells 118 do not require multiplexing and, therefore, do not contain any multiplexing circuitry.

In addition to cells 118, die 100 may also include any number of test structures. For instance, test circuitry 114 provides the ability to ensure that the manufacturing process for the actuator arms was performed correctly. A test signal can be applied to test circuitry 114 and a reading/measurement taken of the expansion rates of the arms of actuator 106, without potentially damaging any of interconnect nodes 102. Likewise, a test signal can be applied to test actuator 116 and a reading/measurement taken to determine the maximum force that test actuator 116 may apply to a pull-rod 110. Other data maybe collected as well, such as the reliability of the manufacturing process, testing for potential reliability of die 100, determining the stress limits of test actuator 116 or the current requirements in order to induce test actuator 116 to move. Any number of different tests can be designed for test circuitry 114 and test actuator 116 beyond those identified here. Also, other test structures besides test circuitry 114 and test actuators 116 may be included on die 100.

While die 100 includes an array of four by four (4×4) cells 118, many other alternate designs could also be fabricated for die 100. For instance, a single row of sixteen cells 118 could be manufactured and identified as die 100. Also, die 100 could contain as few as a single cell 118 or as many cell 118 as the manufacturing process permits on a single wafer. As semi-conductor manufacturing processes change so that greater die densities and larger wafers may be made, a greater number of cells 118 may be included on a single die 100.

Additionally, while cells 118 in die 100 include platforms 108 with cantilevers 112, cells 118 in die 100 could also be made that have platforms 108 that include memory devices. Furthermore, die 100 could include a first group of cells 118 with platforms 108 that include cantilevers 112 and a second group of cells 118 with platforms 108 that include memory devices.

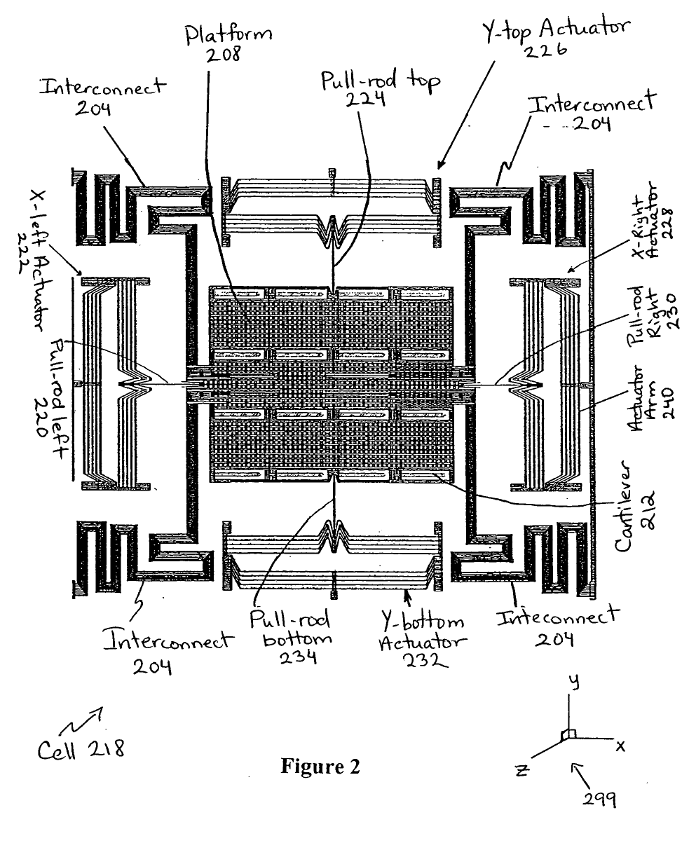

FIG. 2 is a cell 218, which is an extract from cell 118 from FIG. 1 where cell 118 includes a Molecular Array Read/Write Engine (MARE). X-left actuator 222 is coupled with pull-rod left 220, which is in turn coupled with platform 208. Y-top actuator 226 is coupled with pull-rod top 224, which is in turn coupled with platform 208. X-right actuator 228 is coupled with pull-rod right 230, which is in turn coupled with platform 208. Y-bottom actuator 232 is coupled with pull-rod bottom 234, which is in turn coupled with platform 208. Interconnect 204 is coupled with platform 208. While not shown in complete detail, but following FIG. 1, interconnect 204 is also coupled with X-left actuator 222, Y-top actuator 226, X-right actuator 228 and Y-bottom actuator 232. Furthermore, platform 208 is coupled with cantilever 212. As can be seen in FIG. 2, this particular figure displays sixteen cantilevers 212. Moreover, interconnect 204 is includes one or more interconnections that taken in combination are identified as interconnect 204.

All of the actuators (X-left actuator 222, Y-top actuator 226, X-right actuator 228, and Y-bottom actuator 232) include a fault tolerant design such that the actuators will continue to function so long as they are not completely destroyed. When activated, X-left actuator 222 and X-right actuator 228 provide the forces necessary to move platform 208 along the X-axis as defined by reference 299, by pulling on pull-rod 220 and pull-rod 230, respectively. Y-top actuator 226 and Y-bottom actuator 232, subsequently, provide the forces necessary to move platform 208 along the Y-axis as defined by reference 299, by pulling on pull-rod 224 and pull-rod 234, respectively. The actuator (X-left actuator 222, Y-top actuator 226, X-right actuator 228, and Y-bottom actuator 232) movements are typically in the range of plus or minus fifty microns, but this range can be extended or reduced as required by various design goals. Also, all of the actuators (X-left actuator 222, Y-top actuator 226, X-right actuator 228, and Y-bottom actuator 232) are not required to have an identical movement range in order to permit the cell to function. For instance, the X-axis actuators (X-left actuator 222 and X-right actuator 228) could have a range of plus to minus fifty microns while the Y-axis actuators (Y-top actuator 226 and Y-bottom actuator 232) could have a range of plus to minus sixty-five microns, or vice versa. Another example would have X-left actuator 222 and Y-top actuator 226 have a movement of plus and minus twenty microns while X-right actuator 228 and Y-bottom actuator 232 have a movement of plus and minus thirty microns. Any number of different combinations may be used as determined by the design goals for the cell containing the actuators.

The actuators (X-left actuator 222, Y-top actuator 226, X-right actuator 228, and Y-bottom actuator 232) include a fault tolerant design such that actuator reliability is increased. For instance, if one of the arms on an actuator breaks, that arm will form an open circuit. A broken arm will reduce the potential force that an actuator may impose upon platform 208, thereby reducing the maximum range with which the actuator may move platform 208. For instance, suppose X-right actuator 228 was originally designed with ten arms and a force capable of moving platform 208 fifty microns in along the X-axis as defined by reference 299. Now suppose that each of the arms of X-right actuator 228 provide individual forces that equate to a five micron movement (thus, when the ten forces, one for each arm, are taken in combination, a fifty micron movement is possible). If one of the arms of X-right actuator 228 breaks, then the total movement possible by X-right actuator 228 is reduced by five microns, given the assumptions in this example. While X-right actuator 228 is not capable of moving the original fifty microns as it was originally designed, X-right actuator 228 is still capable of moving platform 208 forty-five microns along the X-axis as defined by reference 299. X-right actuator may be designed such that only thirty microns of movement are required to move platform 208 the fullest range required. Hence, four arms could break on X-actuator 228 before the required movement range of platform 208 is actually hindered. Yet, if more arms break on X-right actuator 228, platform 208 is still useful, even though its effective range is reduced. As long as at least four arms of the actuator are unbroken such that they form a complete circuit, X-right actuator 228 is still functional and the platform has utility. X-left actuator 222, Y-top actuator 226, and Y-bottom actuator 232 have similar fault tolerant designs as described for X-right actuator 228.

FIG. 2 shows each actuator (X-left actuator 222, Y-top actuator 226, X-right actuator 228, and Y-bottom actuator 232) with a total of twenty arms 240. Increasing the number of arms 240 may increase the fault tolerance of an actuator, but it will also increase the amount of physical space required for the actuator. Likewise, fewer arms 240, such as six arms, may reduce the amount of physical space required for the actuator, but it will in turn increase the sensitivity that an actuator has to damage, thus reducing its efficiency for being fault tolerant.

Cantilevers 212 may be designed several different ways. One method is to manufacture the cantilevers 212 such that they have their own, independent directional control system. Thus, cantilevers 212 could be designed to be capable of moving along all three axises as defined by reference 299 (x-axis, y-axis, and z-axis). Such a design would require additional interconnections 204 in order to allow control signals to direct cantilevers 212.

Yet another cantilever 212 design is to make the cantilever 212 such that it does not require any independent stimulation to maintain contact with a desired target, or a passive cantilever 212. For instance, the cantilevers 212 are included in a MARE (Molecular Array Read/Write Engine), which is in turn connected with a platform 208 that is part of a cell. The cell maybe moved along the Z-axis, as defined by reference 299, such that the cantilever 212 makes contact with a target platform. Cantilever 212 is then designed to have a curvature such that it curves away from the plane defined by platform 208. Thus, when looking at platform 208 from the side, cantilever 212 will protrude away from platform 208. Consequentially, as a target platform is positioned in close proximity to platform 208 and cantilever 212, the tip of cantilever 212 will make first contact with the target platform. Cantilever 212 maybe designed such that it has a spring like response when pressure is placed upon the cantilever 212 tip. Hence, small changes in the distance between platform 208 and the target platform will not cause cantilever 212 from breaking contact with the target platform. The tip of cantilever 212 may then be positioned within the X/Y plane, as identified by reference 299 and defined by the target platform, through movement of platform 208 by the actuators (X-left actuator 222, Y-top actuator 226, X-right actuator 228, and Y-bottom actuator 232). Additionally, the relative X/Y location of the tip of cantilever 212 to the target platform may also be changed by movement of the target platform in the X/Y plane as defined by the target platform and as referenced by reference 299.

Another option is to make platform 208 so that it is spring loaded. Thus, cantilever 212, which is coupled with platform 208, contacts the target platform, both platform 208 and the target platform could move in the Z-direction. In this mode, fine probe tips (cantilever tips) are formed on cantilever 212 and arrayed around platform 208 to distribute the loading forces of platform 208 on the target platform. This reduces the amount of wear on both the fine probe tips and the target platform.

Yet another option is to place platform 208 inside a recessed cavity. This will provide additional space to permit the platform 208 to move in the Z-direction either through stimuli from the actuators or any spring loading incorporated into platform 208.

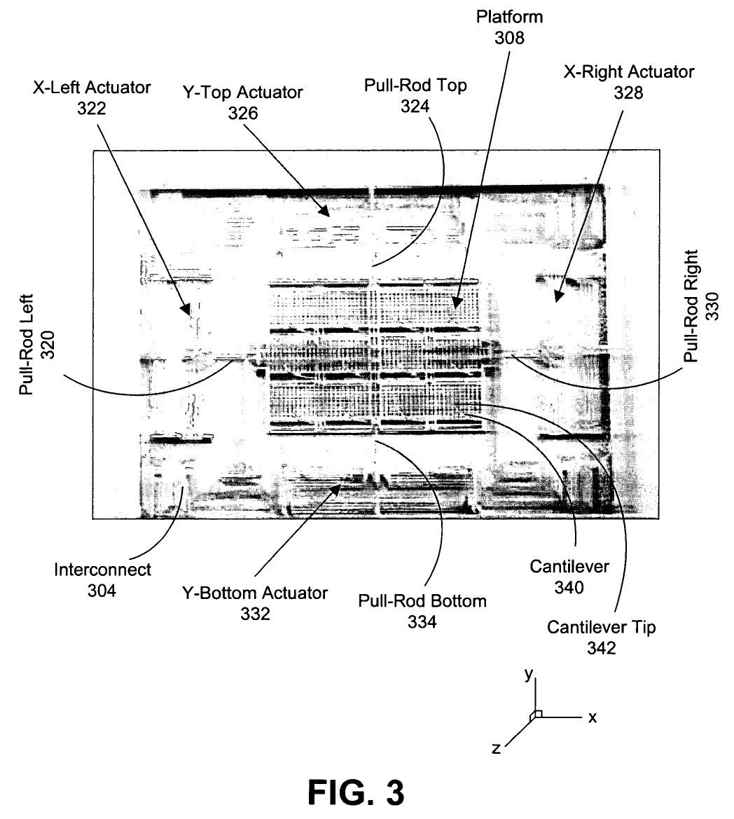

FIG. 3 is a scanning electron microscope picture of a cell 118 from FIG. 1. X-left actuator 322 is coupled with pull-rod left 320, which is in turn coupled with platform 308. Y-top actuator 326 is coupled with pull-rod top 324, which is in turn coupled with platform 308. X-right actuator 328 is coupled with pull-rod right 330, which is in turn coupled with platform 308. Y-bottom actuator 332 is coupled with pull-rod bottom 334, which is in turn coupled with platform 308. Interconnect 304 is coupled with platform 308. While not shown in complete detail, but following FIG. 1, interconnect 304 is also coupled with X-left actuator 322, Y-top actuator 326, X-right actuator 328 and Y-bottom actuator 332. Moreover, interconnect 304 is includes one or more interconnections that taken in combination are identified as interconnect 304. Also shown in FIG. 3. Is a MARE (Molecular Array Read/Write Engine) with sixteen cantilevers 340 each with a cantilever tip 342.

FIG. 3 shows how cantilever 340, which is coupled with platform 308, extends away from platform 308 in the Z-direction as defined by reference 399. At the end of cantilever 340 is a cantilever tip 342. Cantilever tip 342 is the point of contact with a target platform that is brought into close proximity with platform 308. For instance, if a memory device on a target platform is brought into close proximity to platform 308, eventually cantilever tip 342 will make contact with the memory device. For the cell shown in FIG. 3, since there are sixteen cantilevers 340, each with its own cantilever tip 342, there will be sixteen points of contact when the target platform is brought into contact with platform 308. Each cantilever 340 can handle a load force within reasonable limits. For instance, when a target platform makes contact with a cantilever tip 342, the cantilever 340 holds a contact load exerted by the target platform. As a consequence, cantilever 340 is designed to handle some deflection from its position with no load applied. Cantilever 340 is spring loaded such that as a force is applied to the cantilever tip 342, cantilever 340 applies a force back at the target platform, which is asserting the force which has caused cantilever 340 to move from its original position. Consequentially, small movements along the Z-axis as defined by reference 399 will not cause the cantilever tip 342 to break contact with the target platform. Only when the target platform asserts no force against cantilever tip 342 can contact break between cantilever tip 342 and the target platform.

This design provides error control and durability to the design. Such a design could be adjusted to handle a wide range of error forces that could break contact between cantilever tip 342 and the target platform. The hardness of the cantilever tip, the hardness of the device on the target platform, and the friction coefficients of the two materials are several factors determining how much force the cantilever tip 342 maybe subject to before the overall functionality of the micro-electronic mechanical system (MEMS) is impaired. For instance, in a MEMS device designed as a memory device such that the target platform holds a memory device that can be read and written to by the cantilever 340 through the cantilever tip 342, the cantilever tip 342 should be designed to minimize scratches, scars, deformities, etc., caused by cantilever tip 342 to the memory device. Likewise, the cantilever tip 342 must not be to soft as to be damaged by the memory device on the target platform.

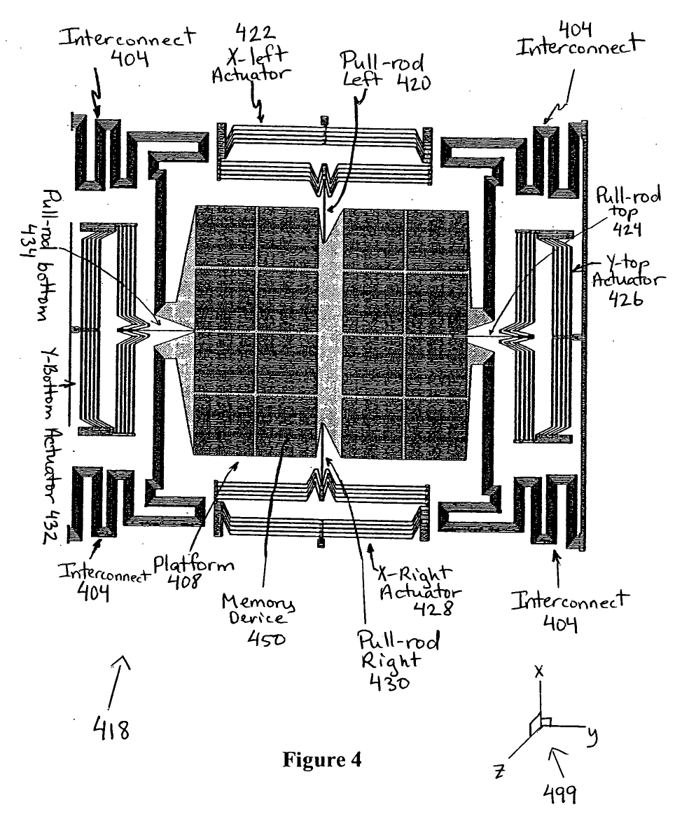

FIG. 4 is a cell 418 that includes memory devices as opposed a MARE (Molecular Array Read/Write Engine) with cantilevers. X-left actuator 422 is coupled with pull-rod left 420, which is in turn coupled with platform 408. Y-top actuator 426 is coupled with pull-rod top 424, which is in turn coupled with platform 408. X-right actuator 428 is coupled with pull-rod right 430, which is in turn coupled with platform 408. Y-bottom actuator 432 is coupled with pull-rod bottom 434, which is in turn coupled with platform 408. Interconnect 404 is coupled with platform 408. While not shown in complete detail, but following FIG. 1, interconnect 404 is also coupled with X-left actuator 422, Y-top actuator 426, X-right actuator 428 and Y-bottom actuator 432. Moreover, interconnect 404 includes one or more interconnections that taken in combination are identified as interconnect 404. Additionally, memory devices 450 is coupled with platform 408. Shown in FIG. 4 are sixteen memory devices 450.

The actuators (X-left actuator 422, Y-top actuator 426, X-right actuator 428 and Y-bottom actuator 432) behave as described for the actuators of FIG. 2. Thus, as the actuators (X-left actuator 422, Y-top actuator 426, X-right actuator 428 and Y-bottom actuator 432) are activated, they exert a force along their corresponding pull-rod (pull-rod left 420, pull-rod top 424, pull-rod right 430, pull-rod bottom 434), respectively. Thus, platform 408 may be moved within the X-Y plane defined by platform 408 and referenced by reference 499. Furthermore, all of the actuators (X-left actuator 422, Y-top actuator 426, X-right actuator 428, and Y-bottom actuator 432) include the fault tolerant design discussed in FIG. 2.

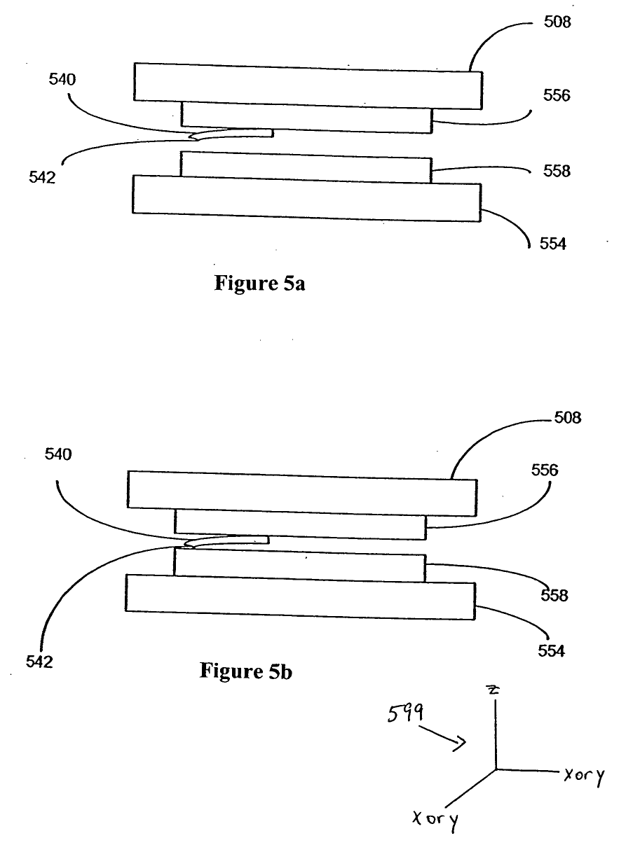

FIG. 5a is a side view of a portion of a platform 508 holding a MARE (Molecular Array Read/Write Engine) 556 from a cell like cell 218 depicted in FIG. 2 positioned over a platform 554 from a cell like cell 418 depicted in FIG. 4 with a memory device 558. As can be seen, cantilever 540 has a curve, which causes cantilever 540 to extend along the Z-axis, as defined by reference 599. The firthest point from platform 508, but still coupled with platform 508, is cantilever tip 542. Cantilever tip 542 is the point that will contact the target device, in this case memory device 558, which is coupled with platform 554.

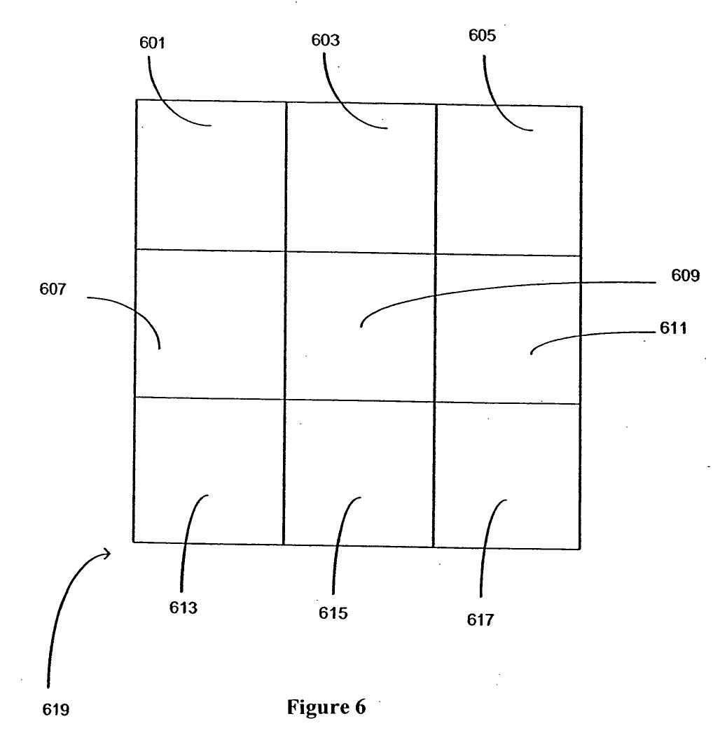

In operation, as shown in FIG. 5b, platform 508 and platform 554 are brought together such that the cantilever tip 542 of cantilever 540 comes in contact with memory device 558. In a typical memory access, a relatively large movement takes place such that the cantilever tip 542 is placed in one of nine quadrants relative to the memory device 558. For instance, in FIG. 6 is shown a top view of a memory device 619 which corresponds to memory device 558 in FIGS. 5a and 5b. The memory device 619 is sectioned into nine sections: top left 601, top middle 603, top right 605, center left 607, center middle 609, center left 611, bottom left 613, bottom middle 615, and bottom right 617. Thus, for a memory access, cantilever tip 542 is first moved to one of the quadrants. For example, for a memory read someplace within the top right quadrant 601, cantilever tip 542 is positioned into the top right quadrant 601. This positioning can be performed in a number of different ways. For instance, platform 508 maybe moved by way of actuators like those in FIG. 2. When platform 508 is moved, then the cantilever 540 that is coupled with platform 508, consequently, moves as well. Eventually, cantilever 540 will be positioned such that cantilever tip 542 will be within the top right quadrant 601. After gross positioning of cantilever tip 542, then fine positioning commences so an individual data bit maybe read or written to by cantilever 540 through cantilever tip 542.

Another method is to move platform 554 by activation of actuators, such as those in FIG. 4, so that the memory device 558 is moved so as to bring the top right quadrant 601 to a position where cantilever tip 542 makes contact with the memory device 558 inside of top right quadrant 601. Yet another method is to move both platform 508 and platform 554 to bring cantilever tip 542 into the top right quadrant 601 of FIG. 6. Similar methods may be used for the remaining quadrants. Also, the memory device 558 could be broken into different formations. For instance, memory device 558 could be broken into three rectangular regions, three horizontal regions, one horizontal region and three smaller vertical regions for four total regions, etc. Again, after a gross positioning step, then fine movements are made to isolate a single data bit. Yet another method would be to skip the gross positioning step and rather make fine, precise movements to a particular location. Gross positioning and fine positioning may also proceed concurrently.

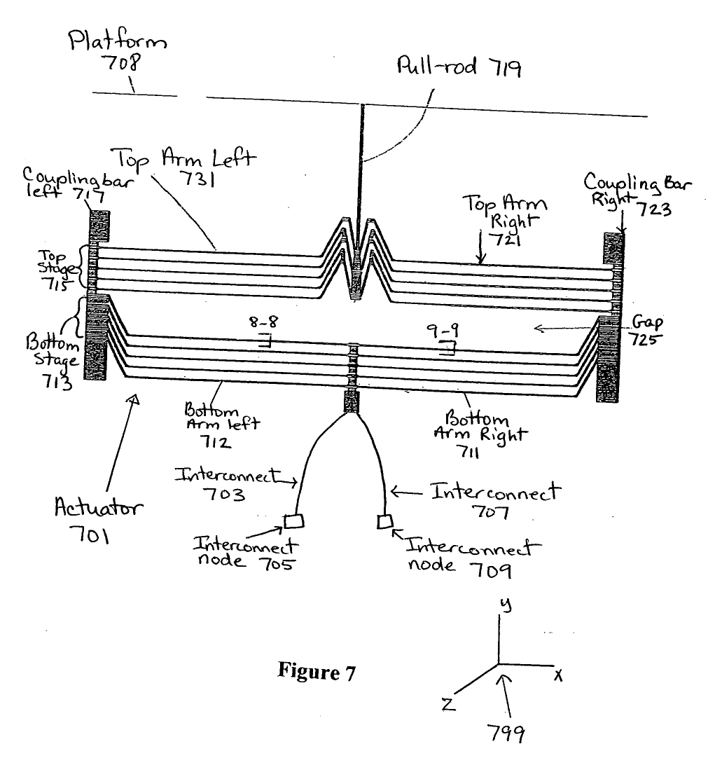

FIG. 7 is an actuator that could be used for any of the actuators in FIGS. 1-4. Actuator 701 includes a top stage 715 and a bottom stage 713. Top stage 715 includes at least one top arm right 721 and one top arm left 731, but as shown in FIG. 7, may have five top arm rights 721 and five top arm lefts 731, or more. Likewise, bottom stage 713 includes at least one bottom arm right 711 and at least one bottom arm left 712, but may have five or more bottom arm lefts 712 and five or more bottom arm rights 711. The top arms (top arms left 731 and top arms right 721) are generally parallel to one another and to the bottom arms (bottom arms left 712 and bottom arms right 711). Separating the top stage 715 from the bottom stage 713 is gap 725. A coupling bar left 717 couples the top stage 715 to the bottom stage 713. Additionally, coupling bar right 723 couples the top stage 715 to the bottom stage 713. Pull-rod 719 couples the top stage 715 to a platform 708. The bottom stage 713 is also connected with a pair of interconnects, interconnect 703 and interconnect 707. Interconnect 703 is also connected with interconnect node 705. Interconnect 707 is also connected with interconnect node 709.

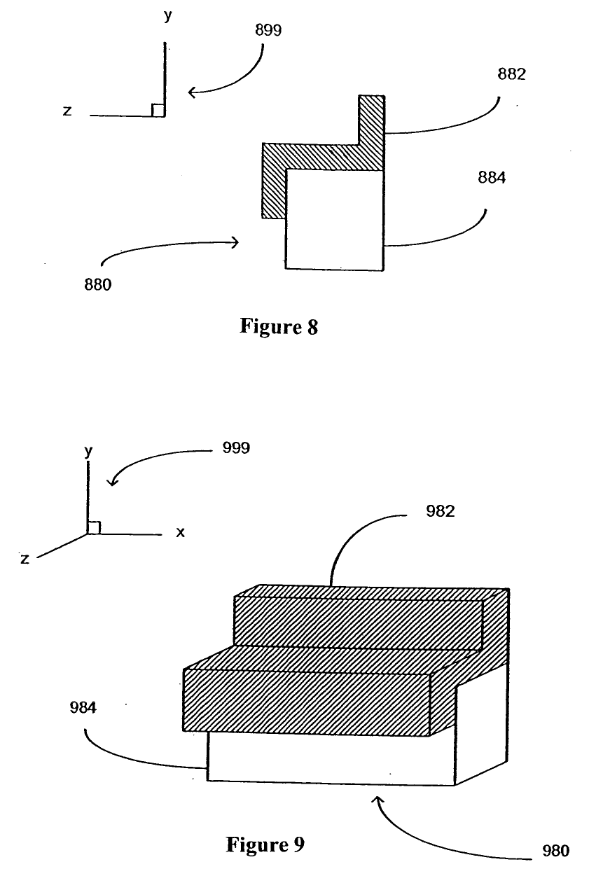

The arms (top arm left 731, top arm right 721, bottom arm left 712, bottom arm right 711) include at least two materials with different coefficients of expansion. FIG. 8 and FIG. 9 show a cross section of an actuator arm. In FIG. 8 is a cross section 880 of line 8-8 in FIG. 7, showing a two-dimensional representation in the Z/Y plane as defined by reference 899. The shaded region 882 is a material that has a higher coefficient of expansion than non-shaded region 884. For instance, material 882 may include titanium, or some other conductor, which has a high coefficient of expansion. Material 884 may include an oxide, or some other insulator, which has a low coefficient of expansion. Likewise, FIG. 9 is a cross section 980 of line 9-9 in FIG. 7, showing a three-dimensional view of actuator arm 980 with a high coefficient of expansion material 982 and a low coefficient of expansion material 984. As a signal is applied to actuator arm 980, such as a current, material 982 will expand at a greater rate than material 984. Consequentially, material 982 will cause the actuator arm 980 to bend generally along the Y-axis in the negative direction as defined by reference 999.

In FIG. 7, reference 799 is consistent with references 899 and 999 in FIG. 8 and FIG. 9, respectively. Thus, the arms of actuator 701 include a high coefficient of expansion material and a low coefficient of expansion material. The high coefficient of expansion material is situated such that it is on the side of the actuator arm towards to platform 708. Thus, the low coefficient of expansion material is located away from platform 708. Hence, as an input signal, like a current, is applied to interconnect node 705 and interconnect node 709, actuator 701 arms (top arm left 731, top arm right 721, bottom arm left 712, bottom arm right 711) heat. As the actuator 701 arms (top arm left 731, top arm right 721, bottom arm left 712, bottom arm right 711) heat, they expand, causing the coupling bar left 717 and coupling bar right 723 to move. The bottom stage 713 causes a movement of the coupling bars (717 and 723) to move some distance, alpha (α). The top stage 715 also causes movement of coupling bars (717 and 723) to move a distance, beta (β). The expansion of the top stage 715 and bottom stage 713 cause the pull-rod 719 to move a distance equal to the combined movement caused by the top stage 715 and the bottom stage 713, or alpha plus beta (α+β). Thus, the fifty micron movement discussed above in FIG. 2 comes from alpha plus beta (α+β). The movement imposed by the top stage 715 and the bottom stage 713 may be identical (α=β), or they may be different (α β). Regardless, as the top stage 715 and the bottom stage 713 heat up, expand, and cause movement of the coupling bar left 717, coupling bar right 723 and pull-rod 719, gap 725 is reduced in size.

The top stage 715 and bottom stage 713 operate in series. So, as an input signal is applied and the actuator 701 arms (top arm left 731, top arm right 721, bottom arm left 712, bottom arm right 711) heat, both the top stage 715 and bottom stage 713 are asserting a force on the coupling bar right 723 and coupling bar left 717 at the same time. Thus, during normal operation with no damage to the device, the actuator arms (top arm left 731, top arm right 721, bottom arm left 712, bottom arm right 711) are not stressed to their operating limits. Only when the actuator 701 is damaged may an actuator arm (top arm left 731, top arm right 721, bottom arm left 712, bottom arm right 711) be forced to operate closer to its maximum range.

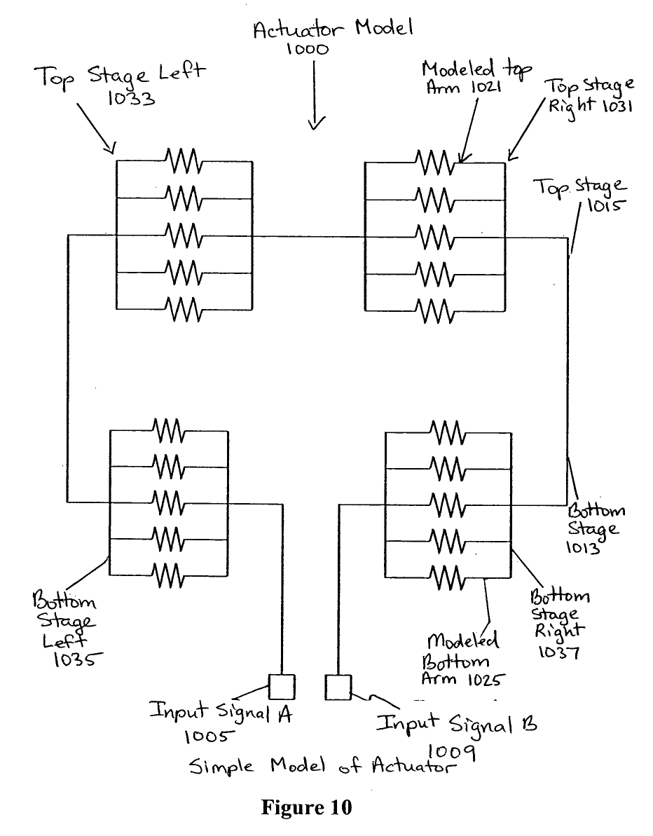

FIG. 10 will help in explaining the loading effects on the actuator 701 change as actuator arms (top arm left 731, top arm right 721, bottom arm left 712, bottom arm right 711) are damaged and become inoperable. FIG. 10 shows a simple electrical model of an actuator is shown in FIG. 10. A top stage 1015 is shown as two separate parallel resister networks. Likewise, bottom stage 1013 is also shown as two separate parallel resister networks. A pair of input signals, input signal 1005 and input signal 1009, are applied to actuator model 1000. The top stage 1031 is modeled with two sides, top stage left 1033 and top stage right 1031. Likewise, bottom stage 1013 is modeled with two stages, bottom stage left 1035 and bottom stage right 1037. Assuming each actuator arm, such as modeled top arm 1021 or modeled bottom arm 1025, has an equivalent resistance of R, then each set of parallel resistor networks would have an equivalent resistance, for an actuator with five arms, (R*R*R*R*R)/(R+R+R+R+R) or (R\hat{ }5)/5R. Thus, if one of the arms breaks thereby removing a resistor from the branch, then the new resistance will be equivalent to (R\hat{ }4)/4R, which is a greater resistance than (R\hat{ }5)/5R. Thus, when an arm breaks, the net effect is that there would be a slight increase in resistance. Consequently, the power of the actuator maybe reduced. Even if an offset is introduced due to an imbalanced actuator, a servo control system should be able to detect and compensate for this difference. Thus, if a top arm left 731 in FIG. 7 broke such that the top stage 715 included four arms on the left and five arms on the right, then to top stage 715 would be out of balance when the actuator 701 was activated. Yet, the top stage 715 would still be able to function, with the high coefficient of expansion material expanding at a greater rate than the low coefficient of expansion material, causing the top stage 715 of actuator 701 to bend, exerting a force along pull-rod 719, and pulling platform 708. While actuator 701 will be unable to exert the same amount of force along pull-rod 719 with a broken top arm left 731, actuator 701 is still capable of exerting a force that is able to move platform 708. Yet, because of the imbalance in the top stage 715, the force applied to pull-rod 719 and on platform 708 might not be squarely along the Y-axis. This imbalance can be sensed by the device in which platform 708 is incorporated and a correction signal applied to either the damaged actuator 701 or another actuator such as the ones described in FIG. 2 (X-left actuator 222, Y-top actuator 226, X-right actuator 228, or Y-bottom actuator 232). Furthermore, actuator 701 will continue to function, although in a less than optimum state, until only one of the arms in each of the four stages is unbroken. If all five of the arms in any stage are broken then there will not be a complete circuit and the actuator model 1000 will not function.

Actuator 701 of FIG. 7 may also be situated such that actuator 701 not only pulls platform 708 along the axis defined by pull-rod 719, but the actuator 701 may also pull the platform 708 along the Z-axis defined by reference 799, into the die holding platform 708. Thus, as the actuator 701 is activated, the platform 708, holding either a MARE (molecular Array Read/Write Engine) or a memory device, is pulled away from a different platform sitting above (or below) platform 708. For instance, if platform 708 held a MARE, which also contains a cantilever, then activation of actuator 701 would pull the MARE away from a memory device that the cantilever on the MARE was making contact. For instance, the actuator could be recessed into the die, slightly below the plane defined by platform 708. One such way to do this is by manufacturing the actuator such that the film stresses recess to the actuator 701. This recess maybe from ten to twenty microns or more. The cantilever on a platform 708 holding a MARE may be designed to adjust for this separation between the two platforms, platform 708 and another platform. This effect will reduce the opportunity for damage to platform 708 and any devices residing on platform 708, such as a MARE or memory device. A typical separation between platforms is from ten to forty microns. This range could be increased or decreased depending on the needs of the design. Yet, the MARE and media device never touch, only the cantilever on the MARE and the media device touch.

The actuator is designed so that only two metal layers are used without any need for an insulating layer between the two metal layers. This is done by preventing the two metal layers from crossing one another except at those points where the two layers are supposed to interact. Thus, while the actuator arms are made with a material with a high coefficient of expansions, like material 982 in FIG. 9, which may be made with titanium, the metal lines forming conductivity connections throughout the remainder of the device, such as interconnects and interconnect nodes, are made with another conductive material, like aluminum. Material 982 and the aluminum metal layer connect on the coupling bars (coupling bar left 717 and coupling bar right 723) of FIG. 7. At this point, as current is fed through material 982 it expands and actuates actuator 701.

One method of manufacturing actuator arms of FIG. 7 and FIG. 9 is to first form the low coefficient of expansion material 984. Then, a trench is cut in front of the low coefficient of expansion material 984. The high coefficient of expansion material 982 is then deposited. A pattern using a resist material may then be laid and etched to form the high coefficient of expansion material 982. Finally, the high coefficient of expansion material 982 is formed into a shape as shown in FIG. 8 and FIG. 9.

The foregoing description of the present invention has been presented for purposes of illustration and description. It is not intended to be exhaustive or to limit the invention to the precise forms disclosed. Obviously, many modifications and variations will be apparent to practitioners skilled in this art. The embodiments were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. A micro-electronic mechanical system actuator, comprising:
an actuator stage coupled with a pull-rod.

2. The micro-electronic mechanical system of claim 1, wherein:
the actuator stage includes an arm composed of a first material and a second material, wherein the first material has a coefficient of expansion that is lower than the second material's coefficient of expansion.

3. The micro-electronic mechanical system of claim 2, including an input signal coupled with the arm.

4. The micro-electronic mechanical system of claim 3, wherein:
the first material is stimulated by the input signal such that the first material expands at a greater rate than the second material.

5. A micro-electronic mechanical system actuator, comprising:
a bottom stage, including a plurality of bottom arms, coupled to a top stage, including a plurality of top arms, through a first coupling bar and a second coupling bar.

6. A method for actuating in a micro-electronic mechanical system, comprising:
supporting a first material with a second material;
applying an input signal;
heating the first material such that the first material expands faster than the second material; and
outputting a movement that is along a direction that passes from the first material to the second material.

7. The method for actuating a micro-electronic mechanical system of claim 6, including:
coupling the output movement with a platform such that the platform is moved as a result of the output movement.

8. A micro-electronic mechanical system actuator, comprising:
a top stage including a top arm, wherein:
the top arm is composed of a first material and a second material; and
the first material has a coefficient of expansion that is lower than the second material's coefficient of expansion;
a bottom stage including a bottom arm, wherein:
the bottom arm is composed of a third material and a fourth material; and
the third material has a coefficient of expansion that is lower than the fourth material's coefficient of expansion; and
a pull-rod that couples the top stage with the bottom stage.

9. A micro-electronic mechanical system actuator, comprising:
a top stage including a first top arm and a second top arm, wherein:
the first top arm is composed of a first material with a low coefficient of expansion and a second material with a high coefficient of expansion;
the second top arm is composed of a third material with a low coefficient of expansion and a fourth material with a high coefficient of expansion;
a bottom stage including a first bottom arm and a second bottom arm, wherein:
the first bottom arm is composed of a fifth material with a low coefficient of expansion and a sixth material with a high coefficient of expansion;
the second bottom arm is composed of a seventh material with a low coefficient of expansion and an eighth material with a high coefficient of expansion.

10. The micro-electronic mechanical system actuator of claim 9, including a first coupling bar that couples the top stage with the bottom stage.

11. The micro-electronic mechanical system actuator of claim 10, including: a second coupling bar that couples the top stage with the bottom stage.

12. The micro-electronic mechanical system actuator of claim 11 wherein the top stage moves when the first top arm and the second top arm are stimulated by an input signal such that the first top arm expands at a greater rate than the second top arm.

13. The micro-electronic mechanical system actuator of claim 12 wherein the bottom stage moves when the first bottom arm and the second bottom arm are stimulated by an input signal such that the first bottom arm expands at a greater rate than the second bottom arm.

14. The micro-electronic mechanical system actuator of claim 13 wherein the first and second coupling bars allow the top stage to move with the bottom stage, and the bottom stage to move with the top stage, thereby increasing the range of motion of the top and bottom stages.

15. The micro-electronic mechanical system actuator of claim 14, including a pull-rod coupled with the top stage.

16. A fault tolerant micro-electronic mechanical system actuator, comprising:
a top stage including a first set of top arms and a second set of top arms, wherein:
each top arm from said first set is composed of a first material with a low coefficient of expansion and a second material with a high coefficient of expansion;
each top arm from said second set is composed of a third material with a low coefficient of expansion and a fourth material with a high coefficient of expansion;
a bottom stage including a first set of bottom arms and a second set of bottom arms, wherein:
each bottom arm from said first set is composed of a fifth material with a low coefficient of expansion and a sixth material with a high coefficient of expansion;
each bottom arm from said second set is composed of a seventh material with a low coefficient of expansion and an eighth material with a high coefficient of expansion.

17. The fault tolerant micro-electronic mechanical system actuator of claim 16 wherein:
one or more of the top arms from the first set and one or more of the top arms from the second set are required to complete a circuit; and
one or more of the bottom arms from the first set and one or more of the bottom arms from the second set are required to complete a circuit.

18. The fault tolerant micro-electronic mechanical system actuator of claim 17, including a first coupling bar that couples the top stage with the bottom stage.

19. The fault tolerant micro-electronic mechanical system actuator of claim 18, including: a second coupling bar that couples the top stage with the bottom stage.

20. The fault tolerant micro-electronic mechanical system actuator of claim 19 wherein the top stage moves when the first set of top arms and the second set of top arms are stimulated by an input signal such that the second material expands at a greater rate than the first material and the fourth material expands at a greater rate than the third material.

21. The fault tolerant micro-electronic mechanical system actuator of claim 20 wherein the bottom stage moves when the first bottom arm and the second bottom arm are stimulated by an input signal such that the sixth material expands at a greater rate than the fifth material and the eighth material expands at a greater rate than the seventh material.

22. The fault tolerant micro-electronic mechanical system actuator of claim 21 wherein the first and second coupling bars allow the top stage to move with the bottom stage, and the bottom stage to move with the top stage, thereby increasing the range of motion of the top and bottom stages.

23. The fault tolerant micro-electronic mechanical system actuator of claim 22, including a pull-rod coupled with the top stage.
